(19) United States
(12) Patent Application Publication
(10) Pub. No.: US 2015/0142352 A1
(43) Pub. Date: May 21, 2015

(54) METHOD FOR DETERMINING A STATE OF ENERGY ON THE BASIS OF DATA ORIGINATING FROM THE PROCESSING METHOD

(71) Applicant: COMMISSARIAT A L'ENERGIE ATOMIQUE ET AUX ENERGIES ALTERNATIVES, paris (FR)

(72) Inventors: Eric Fernandez, Saint Paul de Varces (FR); Tony Delaplagne, Sainte Marie d'Alloix (FR); Romain Franchi, Grenoble (FR); Kelli Mamadou, Fort de France (FR)

(73) Assignee: COMMISSARIAT A L'ENERGIE ATOMIQUE ET AUX ENERGIES ALTERNATIVES, Paris (FR)

(21) Appl. No.: 14/402,408

(22) PCT Filed: May 24, 2013
(86) PCT No.: PCT/EP2013/060796

§ 371 Date: Nov. 20, 2014

(30) Foreign Application Priority Data
May 24, 2012 (FR) 1254793

(51) Int. Cl. G01R 31/36

(52) U.S. Cl. CPC G01R 31/3606; G01R 31/3648
USPC 702/63

(57) ABSTRACT

Method for determining the state of energy of an electrochemical accumulator, characterized in that it comprises the following steps:
using a predetermined set of quadruplets of values relating to operating points of the electrochemical accumulator,
reading (E101) a first state of energy SOE1 from a memory,
measuring (E102) a temperature (T1), and a power (P1), representing the current operation of the accumulator,
determining (E103), on the basis of the predetermined set of quadruplets, a slope of the remaining energy En in the accumulator as a function of the state of energy SOE of the accumulator, at a point representing the first state of energy SOE1, as a function of the measured temperature and measured power (T1, P1),
determining (E104) a second state of energy SOE2 as a function of the determined slope, notably

$$\frac{d En}{d SOE} or \frac{d SOE}{d En} ,$$

of the first state of energy SOE1, and an energy quantity (P·dt).

### TECHNICAL FIELD OF THE INVENTION

The invention relates to the field of electrochemical accumulators.

The subject-matter of the invention is, more particularly, the use of data supplemented with operating points relating to the energy of the accumulator.

In this respect, the invention relates notably to a method for processing a first set of quadruplets of values relating to operating points of an electrochemical accumulator, including power, temperature, state of energy and remaining energy, or power, temperature, state of energy and slope.

### PRIOR ART

Traditionally, the accumulator state indicator is based on an evaluation of the quantity of electrical charges stored in the accumulator. The measurement of the intensity of the current extracted from and/or supplied to the accumulator, associated with an integral calculation, enables the implementation of the “State Of Charge” (SOC) indicator.

In other words, the following formulations are applied:

Q=∂i·dt+Q0

SOC=100·Q/Qmax

where Q is the quantity of charges stored in the battery at time t in coulombs,

Q0 is the quantity of initial charges stored in the battery in coulombs,

Qmax is the maximum quantity of charges of the battery (fully charged battery) in coulombs, and

SOC is a state of charge as a percentage.

This conventional state of charge indicator is not satisfactory in that it does not allow accumulator losses, notably losses due to its internal resistance, to be taken into account.

In fact, the higher the internal resistance of an accumulator is, the lower the quantity of recovered energy will be. Thus, even if the accumulator stores a very large quantity of charges, the quantity of charges really available will be much smaller. The value of the state of charge will therefore be distorted, especially if the internal resistance of the accumulator is high.

A problem has therefore arisen, consisting in finding a different indicator that is more representative of the real state of the accumulator.

A method of characterizing the state of energy of an accumulator is known from document FR2947637.

The aim of this method is to determine some characteristic points of the behaviour of the accumulator which define a set of values SOE (state of energy in Wh), P (useful extracted power in W), En (remaining energy in Wh), which may be represented by mapping in a three-dimensional space as shown in FIG. 1.

The state of energy relates to the energy available at a reference power. This reference power may be the power for which the available energy is the maximum. The “State Of Energy” (SOE) then varies from 0 to 1, or from 0 to 100%. For example, for an accumulator of which the reference energy, at the reference power, is 10 Wh, and by taking an experimental point SOE=50%, P=20 W, En=3 Wh, this means that if the accumulator is used in reality at the power of 20 W, it can deliver the remaining energy of 3 Wh (and not 5 Wh).

The SOE values in FIG. 1 enabling such a reasoning can be determined on the basis of a standard accumulator, or a set of accumulators forming a battery, and are therefore normalized in the laboratory in a controlled environment of power and remaining energy in the accumulator.

This patent application creates problems in terms of using these data notably in the context of an on-board, real-time application where computing resources are limited.

### Object of the Invention

One object of the present invention is to propose a solution overcoming the disadvantages listed above, and enabling the fast calibration/initialization of an accumulator.

A determination method according to the invention is defined by claim 1.

Different embodiments of the determination method are defined by claims 2 to 9.

A determination device according to the invention is defined by claim 10.

A data recording medium according to the invention is defined by claim 11.

A computer program according to the invention is defined by claim 12.

A processing method according to the invention is defined by claim 13.

Different embodiments of the processing method are defined by claims 14 to 18.

### SUMMARY DESCRIPTION OF THE DRAWINGS

Other advantages and characteristics will be more clearly evident from the description which follows of particular embodiments of the invention, given as non-limiting examples and shown on the attached drawings, in which:

FIG. 1 shows the distribution of operating points of an accumulator as a function of the remaining energy, power and state of energy,

FIG. 2 shows an improvement of FIG. 1 in the sense that the operating temperature of the accumulator is also taken into account through experimental characterization,

FIG. 3 shows schematically the method for processing a first set of data, for example such as those shown in FIG. 2 through experimental characterization,

FIG. 4 shows the refinement through interpolation originating from the data in FIG. 2 following the application of the method in FIG. 3,

FIG. 5 shows a particular embodiment of the phase of forming the third set of quadruplets,

FIG. 6 shows a graph representing the modelling of the operating points at fixed power and temperature of the remaining energy as a function of the state of energy,

FIG. 7 shows the steps of a method for estimating the state of energy of an accumulator,

FIG. 8 shows different possible steps for the calculation of a slope value,

FIG. 9 shows a curve representing the state of energy as a function of time, and a curve representing the change in the voltage of an accumulator as a function of time in a phase of validation of the method for determining the state of energy.

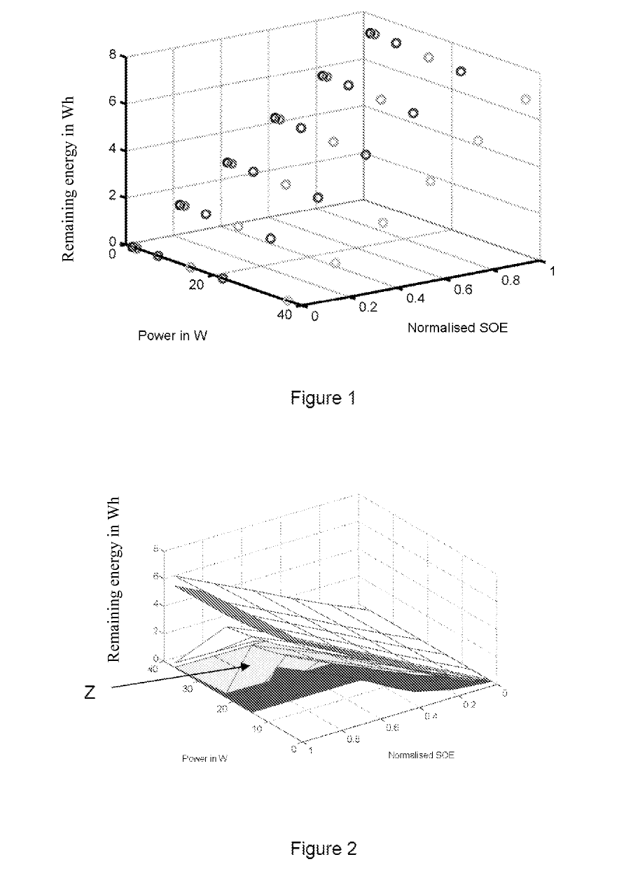

### DESCRIPTION OF PREFERRED EMBODIMENTS OF THE INVENTION

In the context of an on-board application, management of the resources for determining a state of energy is a parameter that must not be ignored. It has therefore been proposed to start with a first set of values relating to operating points of an electrochemical accumulator. Each point includes a power P, a state of energy SOE and a remaining energy En, or a power P, a state of energy SOE and a slope

$$\frac{d En}{d SOE} ,$$

combined by taking account of an additional variable which is the temperature T. The temperature has been integrated since it influences the behaviour of the internal resistance of the electrochemical accumulator.

In other words, the first set may represent quadruplets, presented, for example, in the form of a table En=f(SOE, P, T) or a table

$$\frac{d En}{d SOE} = f ( SOE , P , T ) .$$

These data may be represented in the form of mappings as shown in FIG. 2. FIG. 2 shows a three-dimensional space formed by the remaining energy in Wh, the power in W and the state of energy SOE. Each layer of this space delimits, as a function of its meshing, a virtual surface associated with a temperature (5 temperatures in the example). Each mesh of each layer corresponds to an operating point determined through experimental measurement as a function of the quadruplet (SOE, remaining energy, power, temperature). The number of operating points is quite small because, even if the experiments are automated, their duration is long. A need to supplement these initial mappings thus arises.

Before detailing the steps of one embodiment of the invention, a number of definitions should first be provided.

A “State Of Energy” SOE is defined as the ratio of the remaining energy E_{d/PN} available at the time t assuming a discharge of energy under the nominal conditions of the accumulator to the total nominal energy E_{Nom}, defined therefore by the formula SOE=E_{d/PN}/E_{Nom}. This SOE value is between 0 and 1, the value equal to 1 corresponding to a state of charge of the fully charged accumulator and the value equal to 0 as a fully discharged state. This value can also be expressed as a percentage.

The power P lies within a usage power range recommended by the accumulator manufacturer, or directly supplied by this manufacturer, or derived, for example, from a current range supplied by this manufacturer, through multiplication by a nominal supplied voltage. This power is a function of the state of use of the accumulator, i.e. the charge or discharge. In the case of discharge, the power P will be said to be taken from the accumulator, and in the case of charge, the power P will be said to be supplied to the accumulator. The power P available at the time t may depend on the state of energy and temperature.

The charged and discharged states are determined according to the accumulator technology. They can be obtained from the recommendations of the accumulator manufacturer, and generally from threshold voltages.

The remaining energy En corresponds to the useful energy of the accumulator, it is expressed in Wh and takes account of the internal energy really stored in the accumulator, and the energy lost through the Joule effect in the internal resistance of the accumulator. The following is thus obtained:

En=Ei−Ep

Where

Ep=∫r·I²·dt is the energy lost through the Joule effect in the internal resistance of the accumulator, and

Ei=Q·U is the internal energy stored in the accumulator.

The notion of slope is associated with the remaining energy as a function of the state of energy. It advantageously corresponds to a value, for a fixed power and temperature, of the slope evaluated locally at a point formed by a remaining energy/state of energy pair of a curve passing through all of the points originating from the remaining energy/state of energy pairs, and associated with the same power and at the same temperature. Thus, the slope can be associated with

$$\frac{d En}{d SOE}$$

or with its inverse

$$\frac{d SOE}{d En} .$$

Generally, in the present description, the slope

$$\frac{d En}{d SOE} or \frac{d SOE}{d En}$$

can be replaced with the slope of the remaining energy En in the accumulator as a function of the state of energy SOE of the accumulator.

The first set of quadruplets can be generated as described in the French patent application published under number FR2947637 by also taking account of the temperature (FIG. 2). The generation of this first set will not therefore be described again in detail here. Although the French patent application does not describe how a table giving

$$\frac{d En}{d SOE} = f ( SOE , P , T )$$

is obtained, it is clear that the person skilled in the art will know how to process the information of the French patent application in order to obtain this table. Typically, at each point of the initial table, a slope (En(i+1)−En(i))/(SOE(i+1)−SOE(i)) can be calculated, where i represents the row in the initial table.

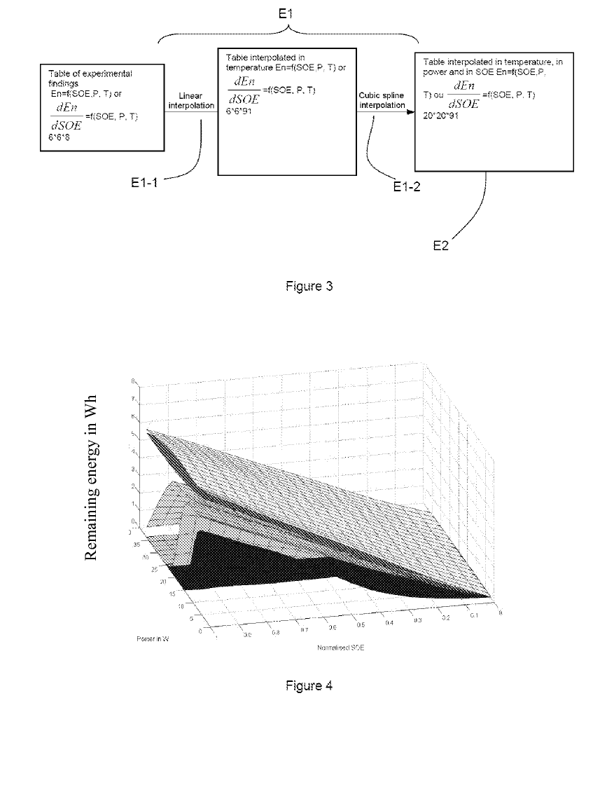

FIG. 3 shows an implementation of the method for processing a first set of quadruplets of values relating to operating points of an electrochemical accumulator, including power P, temperature T, state of energy SOE and remaining energy En, for example of the type En=f(SOE, P, T), or power P, temperature T, state of energy SOE and slope, for example of the type

$$\frac{d En}{d SOE} = f ( SOE , P , T )$$

or its inverse.

This processing method includes a phase E1 of generating a second set of quadruplets through interpolation on the basis of the first set of quadruplets, the generation phase, including the following steps:
carrying out E1-1 an interpolation, notably a linear interpolation, in temperature T,
carrying out E1-2 an interpolation, notably a cubic spline interpolation, in power P and in state of energy SOE.

The advantage of the linear interpolation in temperature is that it is simple to perform in terms of calculation simplicity. In the case of the cubic spline interpolation in power and in state of energy, it enables more regular and monotonic results to be obtained.

The method furthermore comprises a phase E2 of forming a third set of quadruplets, in particular on the basis of the first and second sets of quadruplets.

Advantageously, the third set of quadruplets comprises values relating to operating points of an electrochemical accumulator, including power (P), temperature (T), state of energy (SOE) and slope of the remaining energy En in the accumulator as a function of the state of energy SOE of the accumulator

$$( \frac{d En}{d SOE} or \frac{d SOE}{d En} )$$

on the basis of at least the second set of quadruplets.

In fact, this phase E2 of forming the third set of quadruplets can, more generally, be implemented at least on the basis of the second set of quadruplets. In other words, the third set of quadruplets can in fact be formed by only the second set of quadruplets. According to this implementation, the phases of generation E1 and formation E2 make up only one single common phase.

According to one embodiment, the phase of forming the third set of quadruplets is defined by the union of the first and second sets of quadruplets.

In fact, the notion of “interpolation” consists in determining, on the basis of a succinct statistical series, in this case the first set of quadruplets, new values corresponding to an intermediate character for which no experimental measurement has been carried out. In other words, the first and second sets of quadruplets are advantageously separate. The union of the first and second sets thus enables a third set to be obtained, containing the largest possible number of values.

The known operating points of the accumulator, on the basis of the first set of quadruplets, generally originating from experimental data and measured on a standard accumulator, are thus supplemented. This can be implemented upstream of the on-board application on powerful machines, in such a way that the on-board application can use these results without carrying out too many complex calculations.

The particular example in FIG. 3 shows that, firstly, the interpolation in temperature, preferably through linear interpolation, can be carried out on the basis of the first set of quadruplets, formed in the example by par En=f(SOE, P, T). And, secondly, the interpolation in power and in state of energy, for example spline cubic interpolation, is carried out on the basis of an intermediate set obtained during the interpolation in temperature. The second set therefore advantageously corresponds to the union of the intermediate set and the set obtained through interpolation in power and state of energy of this intermediate set.

The intermediate set can therefore correspond to the union of the first set with the data obtained during the interpolation in temperature. The third set therefore corresponds to the union of the intermediate set and the set obtained through interpolation in power and state of energy of this intermediate set.

In the particular example of FIG. 3, on the basis of experimental findings, an original table of the type En=f(SOE, P, T) is obtained, giving the remaining energy values for the combinations of six different values of SOE, six different values of power P, and eight different values of temperature T.

The, preferably linear, interpolation in temperature is carried out in order to obtain a series of data by degrees Celsius, or 91 series of six powers by six states of energy consecutively in step E1-1.

Each of these series is then subjected to an interpolation, preferably a cubic spline interpolation, of twenty powers and twenty states of energy (step E1-2).

FIG. 4 shows a representation of the example of interpolation in power and in state of energy SOE. To enable a clear reading of FIG. 4, the interpolation in temperature is not shown, and only 5 layers associated with the experimental temperatures out of the 91, following interpolation, are shown.

Thus, on the basis of experimental data of six points of SOE, six points of power P, eight points of temperature T, i.e. 288 points of energy, a set of twenty points of SOE, twenty points of power P, ninety-one points of temperature T, i.e. 36400 points of energy, is generated.

With a double-precision floating-point value encoding, i.e. 8 bytes per value, the third set can occupy 36400×8=291200 bytes.

The interpolation over 91 temperatures is practical, since it is directly in degrees Celsius over a generally considered operating range of the accumulators. The person skilled in the art will obviously be able to adapt the interpolation in temperature according to the intended use of the accumulator.

A comparison between FIG. 2 and FIG. 4 reveals that the irregularities are smoothed in one layer in FIG. 4, thus enabling a more precise estimation of the state of charge to be implemented in future.

In total, the memory size required to accommodate the mapping of this example is in the order of 300 kbytes, which causes no electronic integration problem, notably in on-board applications.

By taking Np as the number of graduations of interpolated powers, Nsoe as the number of interpolated graduations in the state of energy, and Ntemp as the number of interpolated graduations in temperatures, the number of quadruplets present in the memory will be Ntemp*Np*Nsoe.

Table I below evaluates the memory size resources (in kbits or in kbytes) to store the third set as a function of the values of Ntemp, Nsoe and Np and the number of coding bits.

TABLE 1

| | | | Energy | Memory | |
|---|---|---|---|---|---|
| Np | Nsoe | Ntemp | coding (bits) | size (kbit) | Memory size (kbyte) |
| 10 | 10 | 91 | 16 | 146 | 18 |
| 10 | 10 | 91 | 32 | 291 | 36 |
| 10 | 10 | 91 | 64 | 582 | 73 |
| 20 | 20 | 91 | 16 | 582 | 73 |
| 20 | 20 | 91 | 32 | 1165 | 146 |
| 20 | 20 | 91 | 64 | 2330 | 291 |
| 40 | 40 | 91 | 16 | 2330 | 291 |
| 40 | 40 | 91 | 32 | 4659 | 582 |
| 40 | 40 | 91 | 64 | 9318 | 1165 |
| 100 | 100 | 91 | 16 | 14560 | 1820 |
| 100 | 100 | 91 | 32 | 29120 | 3640 |
| 100 | 100 | 91 | 64 | 58240 | 7280 |
| 100 | 100 | 25 | 16 | 4000 | 500 |
| 100 | 100 | 25 | 32 | 8000 | 1000 |
| 100 | 100 | 25 | 64 | 16000 | 2000 |

Even with a priori liberal data interpolations and codings: 100×100×91 in 64 bits, the memory size remains reasonable, i.e. less than 8 Mbytes, which can be readily integrated on an electronic card.

The fineness of the interpolation must be optimized according to the required precision of the state of energy estimation. The more irregular the state of energy functions are in relation to the usage power and the temperature (see area Z in FIG. 2), the more advantageous a larger number of modelling/operating points will be.

The number of operating points can also be increased only in places where irregularities occur, by carrying out a larger number of interpolations in these places. This can reduce the size of the memory containing the mapping at the expense of the simplicity of searching in the memory when the application is running.

The mappings, i.e. the additional operating points originating from the interpolations, can be computer-generated using scientific calculation software. Software suites such as matlab, mathcad, octave and scilab can typically be used.

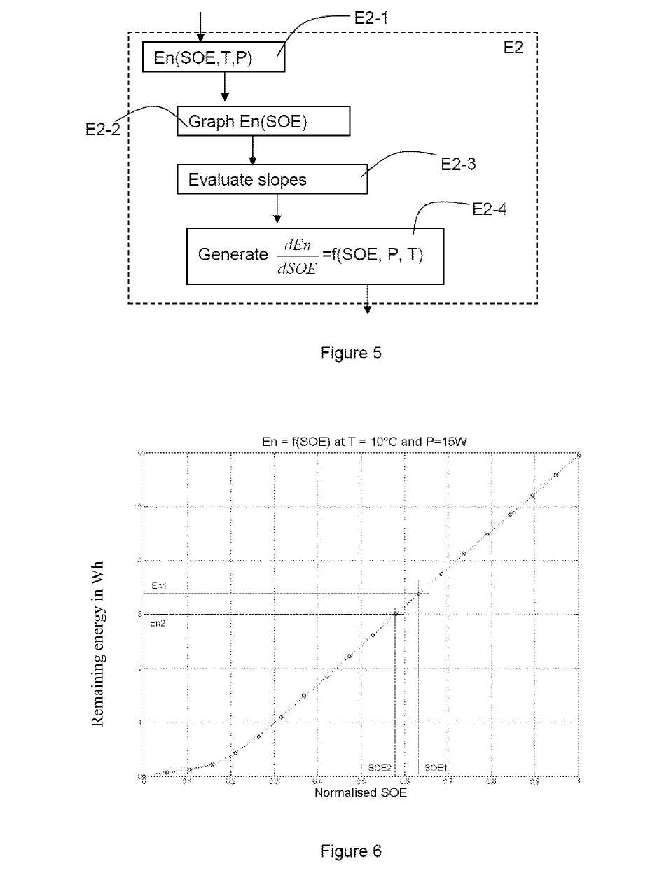

According to one particular embodiment shown in FIG. 5, the first set of quadruplets and the second set of quadrupeds relate to operating points of an electrochemical accumulator, including power P, temperature T, state of energy SOE and remaining energy En, i.e., for example, of the type En=f(SOE, P, T). And the phase of forming the third set of quadruplets comprises, on the basis of the first and second sets of quadruplets, a step of determining the third set of quadruplets of operating points of the electrochemical accumulator, including power P, temperature T, state of energy SOE and slope

$$\frac{d En}{d SOE} ,$$

i.e., for example, of the type

$$\frac{d En}{d SOE} = f ( SOE , P , T )$$

This can be implemented after the interpolations in temperature and in power and state of energy, and advantageously on a set of quadruplets representing at least the union of the first set and the second set (step E2-1). In this case, the slope

$$\frac{d En}{d SOE}$$

can be obtained for each combination of temperature T and power P, advantageously of the third set of quadruplets, in the following manner:
determining a set of remaining energy/state of energy pairs, each pair forming a point of coordinates formed by the remaining energy and the state of energy,
evaluating E2-3, for each pair of the set of pairs, an associated slope value as a function of the point of the processed pair and a different point associated with a different pair.

In other words, it is as if a graph of the remaining energy as a function of the state of energy were implemented E2-2 in which each remaining energy/state of energy pair forms a point on the graph, before evaluating E2-3 locally, at each point of the graph, the slope representing a curve passing through all of the points on the graph. The step E2-2 in FIG. 5 and the graph in FIG. 6 are shown merely to illustrate the explanation of the method, the step E2-2 not being carried out by the method.

The person skilled in the art will be able to carry out the local evaluation of the slope by conventionally taking account of the preceding or following point of the curve. The slope will preferably be a positive value, and, if it is negative, this involves an edge effect of the interpolation. In fact, a negative slope has no physical meaning and this would mean that the state of energy of the accumulator increases while it is being discharged. In fact, the remaining energy and the state of energy change in the same direction. However, following the interpolation in power and state of energy, some slopes turn out to be negative, in which case these slopes are limited to a positive value slightly greater than 0 in order to reflect even a weak discharge (or charge) when an energy is extracted (or supplied).

According to one variant, the first set relates to quadruplets of values relating to operating points of the electrochemical accumulator, including power P, temperature T, state of energy SOE and slope

$$\frac{d En}{d SOE}$$

and the method includes a prior step of determining the first set on the basis of a fourth set of quadruplets of values relating to operating points of an electrochemical accumulator, including power P, temperature T, state of energy SOE and remaining energy En. The slope can then be determined in the same way as described above.

FIG. 6 shows, for a temperature fixed at 10° C. and a power of 15 W, the graph showing the remaining energy in Wh as a function of the state of energy SOE. The hypothetical curve is shown as a dotted line and passes through all of the points of the graph.

After having evaluated the slopes locally and at each point (remaining energy/state of energy), it is easy to obtain a table combining power, temperature, state of energy and slope and advantageously giving

$$\frac{d En}{d SOE} = f ( SOE , P , T )$$

in a step E2-4, this table then representing the third set.

The third set as formed in the method above in all its variants can be used in a general manner in a method for determining the state of energy of an electrochemical accumulator. This method will advantageously be carried out in real time in an on-board application.

It will then be understood that the method for determining the state of energy advantageously uses the third set of quadruplets. However, alternatively and in a general manner, the method comprises a step in which a predetermined set of quadruplets of values relating to operating points of an electrochemical accumulator is used, including power P, temperature T, state of energy SOE and remaining energy En, or to operating points of an electrochemical accumulator, including power P, temperature T, state of energy SOE and slope of the remaining energy En in the accumulator as a function of the state of energy SOE of the accumulator, notably a slope

$$\frac{d En}{d SOE} or \frac{d SOE}{d En} .$$

This predetermined set can then be the third set of quadruplets or can be obtained in other ways. Thus, in the description below, the third set of quadruplets can advantageously be replaced by the predetermined set of quadruplets.

The division into a third set as described, which places the modelling and complex calculations outside the real-time application, associated with a relatively simple iterative calculation and some measures to be carried out during the running of the real-time application, which will be developed below, gives access to a state of energy indicator which can easily be integrated into the electronics of a Battery Management System (BMS).

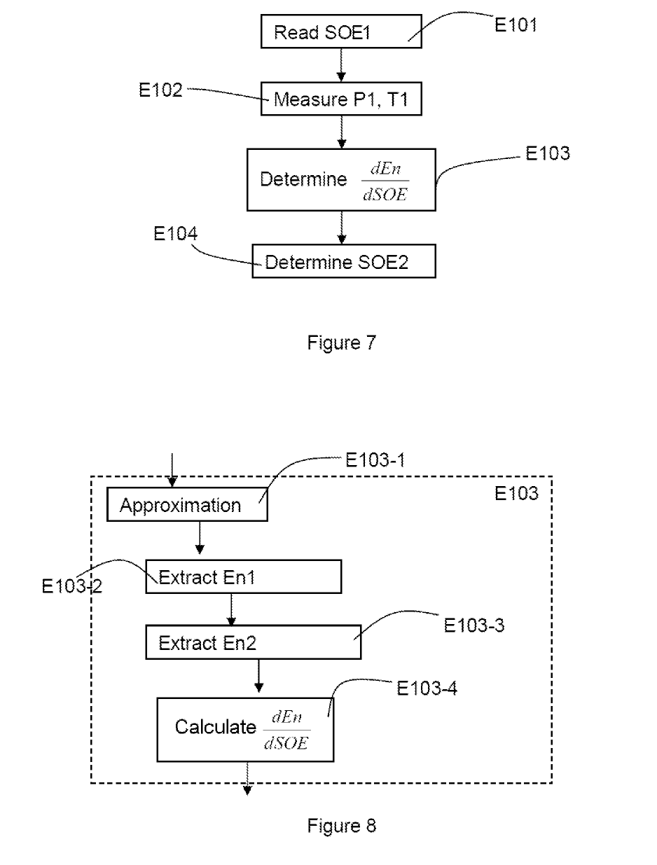

FIG. 7 shows a particular implementation of the method for determining the state of energy of a accumulator. This, advantageously iterative, method comprises a step E101 in which a first state of energy SOE1 is read from a memory. In the case where the method is iterative, the value SOE1 corresponds to the state of energy of the accumulator determined in the preceding step. In other words, if necessary, at the end of each iteration, the method advantageously comprises a step of replacing the value of the first state of energy SOE1 in the memory with the value of a second state of energy SOE2, representing the state of energy which was to be determined during the iteration (also referred to as the current state of energy), and which will be used as the first state of energy in the following iteration.

In the very first initialization state, the accumulator can be charged to its maximum, and, when the charging stops, the value of the memory represents 100%. Or, conversely, the accumulator can be totally discharged, and the value stored at the time of the initialization can represent 0%.

Then, in a step E102, the temperature T1 and the power P1 representing the current operation of the accumulator are measured. The term “current” is understood to mean the state of operation during the iteration. The terms “Temperature and power representing the accumulator” are understood to mean the power at which the energy is taken from or supplied to the accumulator, and the operating temperature of the accumulator. Here, the power is signed, i.e. it can be positive or negative. A positive power will represent an accumulator charging phase and a negative power will represent an accumulator discharging phase. The set of quadruplets can therefore comprise positive and negative power values. The temperature representing the accumulator must be the closest to its internal temperature, so it is possible to place a temperature sensor in the accumulator if the technology of the sensor can resist the electrolyte. Obviously, the temperature sensor will advantageously be placed in the same location as the temperature sensor of a standard accumulator having served to form the first set. Although it is possible to have a table comprising positive and negative power values, for the sake of simplification the table entry is the absolute power value.

In a step E103, the slope

$$\frac{d En}{d SOE}$$

of the remaining energy En in the accumulator as a function of the state of energy SOE of the accumulator at a point representing the first state of energy SOE1, as function of the measured temperature T1 and measured power P1, is determined on the basis of the third set of quadruplets. This slope

$$\frac{d En}{d SOE}$$

can be determined through simple reading if, for example, the third set of quadruplets is of the type

$$\frac{d En}{d SOE} = f ( SOE , P , T )$$

or can be obtained through calculation if, for example, the third set of quadruplets is of the type En=f(SOE, P, T).

Finally, a second state of energy SOE2, a function of the determined slope

$$\frac{d En}{d SOE} ,$$

of the first state of energy SOE1, and an energy quantity, is determined during step E104.

This second state of energy SOE2 corresponds to the current state of energy of the accumulator which is to be determined, and takes account of its operating variables of measured power P1 and measured temperature T1.

In order to limit the calculations in the context of an on-board application, it is advantageous to implement approximations during the different steps of the method of determining the state of energy SOE.

Thus, the slope

$$\frac{d En}{d SOE}$$

is obtained through approximation of at least one of the following values of measured temperature T1, measured power P1, the first state of energy SOE1, at an associated value contained in the third set of quadruplets. All these values are advantageously approximate, notably if they do not form part of those contained in the third set.

In fact, according to the resolution of the measurement sensors, the measured values of temperature T1 and power P1, or the state of energy SOE1 that is read may correspond to values not forming part of the third set of quadruplets. In order to limit the resources of the on-board application, it is advantageous if the determination of the state of charge takes account of discretized values, i.e. contained in the third set. To do this, the approximation may correspond to choosing a closest associated value of the third set, or to choosing an immediately lower associated value of the third set. Obviously, if values included in the third set are directly encountered, the approximation will not be necessary. The choice of a closest value enables a more precise result than the choice of the immediately lower value.

Advantageously, the second state of energy SOE2 is obtained by applying the formula

$$SOE 2 ≅ SOE 1 + P \cdot dt \cdot \frac{d SOE}{d En} ,$$

where P·dt is the energy quantity. In fact, the energy quantity is associated with a positive power value supplied to the accumulator during a determined period during a charging phase, or with a negative power value output by/taken from the accumulator during a determined period during a discharging phase.

Thus, before determining the state of energy SOE2, the method can check whether the accumulator concerned is in the charging or discharging phase. This can be carried out by any suitable means known to the person skilled in the art, for example by measuring the current.

As mentioned above, the energy quantity corresponds to the energy taken or supplied. In terms of value, it corresponds to Qenergy=(En2−En1), where En1 corresponds to the remaining energy associated with SOE1, and En2 corresponds to the remaining energy associated with SOE2 (see FIG. 6). This energy can be calculated in such a way that Qenergy=U·I·dt=P·dt. The time derivative dt corresponds to the time duration of the determined period. It has previously been explained that the method could be iterative, wherefore, advantageously, the determined represents, or is equal to, the iteration period of the method. In the particular case where the slope must be calculated, the step E103 of FIG. 7 is detailed in FIG. 8. First of all, an approximation is carried out E103-1 by choosing for the measured temperature T1, the measured power P1 and the first state of energy SOE1, an approximated temperature T1app, an approximated power P1 app and a first approximated state of energy SOE1app respectively. The approximation of the corresponding value can be carried out by taking, for the approximated temperature and approximated power, the corresponding value equal to the measured value, or immediately below the measured value, or closest to the measured value, and present in the third set of quadruplets, for example of the type En=f(SOE, P, T). For SOE1app, the value equal to the value of SOE1 or immediately below SOE1 and comprised in the third set will be preferably taken. A first remaining energy En1, a function of the approximated temperature T1app, approximated power P1 app and approximated first state of energy SOE1app, is then extracted E103-2 from the third set of quadruplets, through simple reading since it entails a combination of known and stored values in the third set of quadruplets. Furthermore, a second remaining energy En2, a function of the approximated temperature T1app and approximated power P1 app, and a second approximated state of energy SOE2app contained in the third set and indexed in a row directly above the row associated with the first approximated state of energy SOE1 app is extracted E103-3 from the third set of quadruplets, again through simple reading for the same reasons as those mentioned above. The term “higher index” is understood to mean the value SOE2app immediately above SOE1app for the given combination T1app and P1 app. Although in FIG. 8 the step E103-2 is carried out before the step E103-3, this sequence is irrelevant since, at the time of the calculation of the slope E103-4 values associated with En1, En2, SOE1 app and SOE2app are present.

Finally, the slope

$$\frac{d En}{d SOE}$$

is calculated E103-4 according to the formula

$$\frac{d En}{d SOE} = ( En 1 - En 2 ) / ( SOE 1 app - SOE 2 app ) .$$

This slope value can then be the value used in step E104 in FIG. 7.

It follows from the previous statements that the use of a third set of the type

$$\frac{d En}{d SOE} = f ( SOE , P , T )$$

is advantageous in the context of an on-board application, since the slope is directly available. This limits all the more the resources of an on-board computer carrying out the method of determining the state of energy, and allows a current value of the state of energy of the accumulator to be obtained more quickly.

It is not impossible for the power or temperature to change between two successive iterations. In this particular case, during an iteration, the determination of the current state of energy takes account of the change in temperature and/or power in relation to the preceding iteration.

In fact, by reading the memory in order to determine the value SOE1 and by determining the slope on the basis of the third set of quadruplets as a function of the measured temperature and measured power, the change in temperature or power is automatically taken into account. From the preceding iterative calculation, only the state of energy (i.e. SOE1 during the new step) is retained. On the basis of the new measurements, the new power and new temperature are determined which enable the table to be accessed in order to determine the remaining energy or the slope, and then the new state of energy SOE2 to be calculated. In principle, the power and temperature variations are therefore taken into account.

It is possible for the formula

$$SOE 2 ≅ SOE 1 + P \cdot dt \cdot \frac{d SOE}{d En}$$

to be temperature-corrected. It will then be replaced with

$$SOE 2 ≅ SOE 1 + eff Ch \cdot P \cdot dt \cdot \frac{d SOE}{d En} ,$$

where effCh is a correction coefficient, a function of the charging or discharging. The use of the correction coefficient avoids the use of a table associated with the charging and a table associated with the discharging, and will therefore be preferred since it requires less storage.

The power can be measured on the basis of values of accumulator voltage and of current passing through the accumulator.

A computer-readable data recording medium on which a computer program is recorded may include computer program code means for carrying out the steps and/or phases of the processing and/or determination methods mentioned above.

Similarly, a computer program may include a computer program code means suitable for carrying out the steps and/or phases of the determination and/or processing method when the program is executed by a computer. The invention also relates to a device for determining a state of energy of a accumulator, including hardware and/or software means to carry out the steps of the determination and/or processing method (or more particularly to carry out the determination and/or processing method). Typically, the device may comprise a memory in which the third set is integrated, for example in the form of a database of which the primary keys are power, temperature and state of energy, giving either a single remaining energy value, or a single slope value. This device may comprise the recording medium and/or the computer program described above.

It will then be understood from the statements above that the computer program of the recording medium may include computer program code means executable by the software means of the device as described for carrying out the determination and/or processing method.

Furthermore, it will also be understood that the computer program may include a computer program code means executable by software means of the device as described in order to carry out the determination and/or processing method, notably when the program is executed by a computer.

Thus, in real time, the device enables the exact operating point of the accumulator to be determined quickly in order to extract a precise and consistent state of energy value.

The method for determining the state of energy as described above was tested on a usage profile in order to check its effectiveness. The test conditions were as follows:
application to an accumulator of a power profile, having charging and discharging phases,
measurements of the voltage on the accumulator terminals and of the temperature of the accumulator.

Furthermore, the power profile and the operating temperature of the accumulator were injected into a simulation of the computing algorithm for estimating the state of energy described above.

The results of the simulated state of energy and the voltage really measured can then be compared.

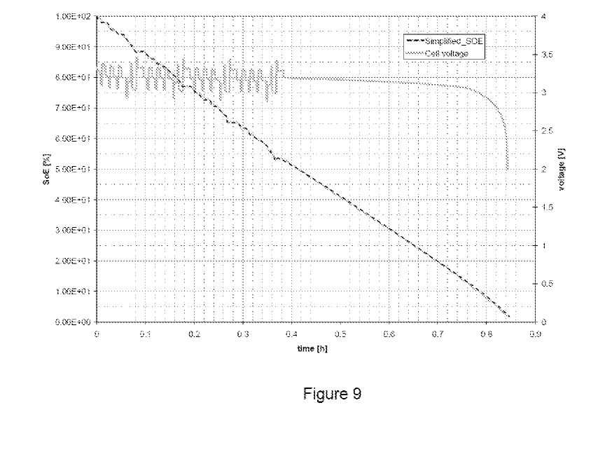

FIG. 9 uses the results. This FIG. 9 shows the state of energy SOE as a function of time, and the variation in the voltage on the accumulator terminals as a function of time. This FIG. 9 shows that, at the end of discharging, when the voltage reaches around 2V, the state of energy (SOE) is in fact close to 0 (1.48%). This margin of error is very small, and is satisfactory in the context of the on-board application.

The description mentions an electrochemical accumulator. The definition of the accumulator must be understood in the broad sense, and refers to one elementary accumulator or a plurality of elementary accumulators arranged in the form of a battery. The accumulator used to carry out the test comes from the manufacturer A123system, reference number ANR26650M1.

1. Method for determining the state of energy of an electrochemical accumulator, which comprises the following steps:
using a predetermined set of quadruplets of values relating to operating points of the electrochemical accumulator, including power (P), temperature (T), state of energy SOE and remaining energy En, or to operating points of the electrochemical accumulator, including power (P), temperature (T), state of energy SOE and slope of the remaining energy En in the accumulator as a function of the state of energy SOE of the accumulator,
reading (E101) a first state of energy SOE1 from a memory,
measuring (E102) a temperature (T1), and a power (P1), representing the current operation of the accumulator,
En in the accumulator as a function of the state of energy SOE of the accumulator, at a point representing the first state of energy SOE1, as a function of the measured temperature and measured power (T1, P1),
determining (E104) a second state of energy SOE2 as a function of the determined slope, of the first state of energy SOE1, and an energy quantity (P·dt).

2. Method according to claim 1, wherein the slope is obtained through approximation of at least one of the following values of measured temperature (T1), measured power (P1), the first state of energy (SOE1), at an associated value contained in the predetermined set of quadruplets.

3. Method according to claim 2, wherein the approximation corresponds to choosing a closest associated value of the predetermined set, or to choosing an immediately lower associated value of the predetermined set.

4. Method according to claim 1, wherein the second state of energy SOE2 is obtained by applying the formula
$$SOE 2 ≅ SOE 1 + P \cdot dt \cdot \frac{d SOE}{d En} ,$$
where P·dt is the energy quantity, and is associated with a positive power value supplied to the accumulator during a predetermined period during a charging phase, or a negative power value output by the accumulator during a predetermined period during a discharging phase.

5. Method according to claim 1, wherein the method is carried out iteratively, and wherein, at the end of each iteration, the method comprises a step of replacing the value of the first state of energy SOE1 in the memory with the value of the second state of energy SOE2 which will be used as the first state of energy in the following iteration.

6. Method according to claim 4,
wherein the method is carried out iteratively, and wherein, at the end of each iteration, the method comprises a step of replacing the value of the first state of energy SOE1 in the memory with the value of the second state of energy SOE2 which will be used as the first state of energy in the following iteration,
wherein the determined period (dt) represents a period of iteration of the method.

7. Method according to claim 1, wherein the slope is obtained through simple reading of the predetermined set of quadruplets.

8. Method according to claim 1, wherein the slope is obtained through calculation on the basis of the predetermined set.

9. Method according to claim 8, wherein the slope, is calculated in the following manner:
carrying out an approximation by choosing, for the measured temperature (T1), the measured power (P1) and the first state of energy (SOE1), an approximated temperature (T1app), an approximated power (P1app) and an approximated first state of energy SOE1app respectively, said approximated temperature and power values being values equal to, immediately below, or closest to the corresponding measured values and present in the predetermined set, the approximated value of the state of energy SOE1app being the value equal to, or immediately below, the first state of energy SOE1 and present in the predetermined set,
extracting, from the predetermined set, a first remaining energy En1, a function of the approximated temperature (T1app), approximated power (P1app) and approximated first state of energy SOE1app,
extracting, from the predetermined set, a second remaining energy En2 as a function of the approximated temperature (T1app) and approximated power (P1app), and a second approximated state of energy SOE2app contained in the predetermined set and indexed in a row directly above the row associated with the first approximated state of energy SOE1app,
calculating the slope, according to the formula
$$\frac{d En}{d SOE} = ( En 1 - En 2 ) / ( SOE 1 app - SOE 2 app ) .$$

10. Device for determining a state of energy of an accumulator, including hardware and software means for carrying out the method according to claim 1.

11. Computer-readable data recording medium on which a computer program is recorded, including computer program code means executable by the software means of a device for determining a state of energy of an accumulator to carry out the method according to claim 1.

12. Computer program, including a computer program code means executable by the software means of a device for determining a state of energy of an accumulator for carrying out the method according to one of claim 1.

13. Method for processing a first set of quadruplets of values relating to operating points of an electrochemical accumulator, including power (P), temperature (T), state of energy (SOE) and remaining energy (En), or to operating points of the electrochemical accumulator, including power (P), temperature (T), state of energy (SOE) and slope of the remaining energy En in the accumulator according to the state of energy SOE of the accumulator, said method including:
a phase (E1) of generating a second set of quadruplets through interpolation on the basis of the first set of quadruplets, the generation phase including the following steps:
a. carrying out an interpolation in temperature (T),
b. carrying out an interpolation in power (P) and in state of energy (SOE),
a phase (E2) of forming a third set of quadruplets of values relating to operating points of an electrochemical accumulator, including power (P), temperature (T), state of energy (SOE) and slope of the remaining energy En in the accumulator as a function of the state of energy SOE of the accumulator on the basis of at least the second set of quadruplets.

14. Method according to claim 13, wherein the forming the third set of quadruplets is defined by the union of the first and second sets of quadruplets.

15. Method according to claim 13, wherein the first set of quadruplets originates from experimental data measured on a standard accumulator.

16. Method according to claim 13, wherein, firstly, the interpolation in temperature is carried out on the basis of the first set of quadruplets, and wherein, secondly, the interpolation in power and in state of energy is carried out on the basis of an intermediate set obtained following the interpolation in temperature.

17. Method according to claim 13, wherein:
the first set relates to quadruplets of values relating to operating points of the electrochemical accumulator, including power (P), temperature (T), state of energy (SOE) and slope
$$( \frac{d En}{d SOE} , \frac{d SOE}{d En} ) ,$$
and wherein the method includes a prior step of determining the first set on the basis of a fourth set of quadruplets of values relating to operating points of an electrochemical accumulator, including power (P), temperature (T), state of energy (SOE) and remaining energy (En), or wherein:
the first and second sets relate to quadruplets of values relating to operating points of an electrochemical accumulator, including power (P), temperature (T), state of energy (SOE) and remaining energy (En), and wherein the forming the third set includes a step of determining the third set of quadruplets of operating points of the electrochemical accumulator, including power (P), temperature (T), state of energy (SOE) and slope
$$( \frac{d En}{d SOE} , \frac{d SOE}{d En} )$$
on the basis of the first and second sets of quadruplets.

18. Method according to claim 17, wherein the slope
$$( \frac{d En}{d SOE} )$$
is obtained for each combination of temperature (T) and power (P) in the following manner:
determining a set of remaining energy/state of energy pairs, each forming a point of coordinates formed by the remaining energy and the state of energy,
evaluating, for each pair of the set of pairs, an associated slope value as a function of the point of the processed pair and a different point associated with a different pair.

19. Method according to claim 1, wherein the function of the state of energy of the accumulator is
$$\frac{d En}{d SOE} or \frac{d SOE}{d En} .$$

20. Method according to claim 13, wherein the function of the state of energy of the accumulator is
$$\frac{d En}{d SOE} or \frac{d SOE}{d En} .$$
